(19) United States
(12) Patent Application Publication
(10) Pub. No.: US 2010/0012177 A1
(43) Pub. Date: Jan. 21, 2010

(54) PHOTON-CONVERSION MATERIALS (PCMs) IN POLYMER SOLAR CELLS-ENHANCEMENT EFFICIENCY AND PREVENTION OF DEGRADATION

(76) Inventors: Yang Yang, Los Angeles, CA (US); Gang Li, Los Angeles, CA (US)

Correspondence Address: VENABLE LLP, P.O. BOX 34385, WASHINGTON, DC, 20043-9998, US

(21) Appl. No.: 12/162,943

(22) PCT Filed: Feb. 16, 2007
(86) PCT No.: PCT/US07/04073

§ 371 Date: Jul. 14, 2009

Related U.S. Application Data
(60) Provisional application No. 60/774,188, filed on Feb. 17, 2006.

(51) Int. Cl. H01L 31/00

(52) U.S. Cl. 136/256

(57) ABSTRACT

A photovoltaic device has a photovoltaic cell and a photon-conversion component. The photon-conversion component has a photon-conversion material in its composition. The photon-conversion material, while the photovoltaic device is in operation, converts photons in a spectral region including a first wavelength to photons in a spectral region including a second wavelength, the second wavelength being longer then the first wavelength. The photons having the second wavelength are at least one of less damaging to the photovoltaic cell than photons having the first wavelength or converted more efficiently to an electrical current than photons having the first wavelength.

### CROSS-REFERENCE TO RELATED APPLICATION

This application claims priority to U.S. Provisional Application No. 60/774,188 filed Feb. 17, 2006, the entire contents of which are hereby incorporated by reference.

### BACKGROUND

1. Field of Invention

The current invention relates to devices and methods for converting electromagnetic energy into electrical power, and particularly to improved photoelectric cells and methods.

2. Discussion of Related Art

It is important for solar cells to exploit as efficiently as possible the full solar spectrum in order to improve power conversion cell efficiencies to a point that practical, widespread, and low-cost utilization is feasible. This is even more important in organic (small molecule and polymer) solar cells, in which the external quantum efficiency (EQE) varies more strongly with the wavelength of the incident light than their inorganic counterparts. In many organic photovoltaic systems, the maximum EQE values lie within the visible range, whereas EQE values in the UV range are smaller. Therefore, conventional organic photovoltaic cells do not convert UV light to electrical power efficiently. Furthermore, the natural exposure of photovoltaic cells to UV light can lead to damage and degradation of the device over time. Therefore, there is a need for improved photovoltaic cells.

### SUMMARY

A photovoltaic device according to an embodiment of the current invention has a photovoltaic cell and a photon-conversion component. The photon-conversion component has a photon-conversion material in its composition. The photon-conversion material, while the photovoltaic device is in operation, converts photons in a spectral region including a first wavelength to photons in a spectral region including a second wavelength, the second wavelength being longer than the first wavelength. The photons having the second wavelength are at least one of less damaging to the photovoltaic cell than photons having the first wavelength or converted more efficiently to an electrical current than photons having the first wavelength.

A method of producing electricity according to an embodiment of the current invention includes converting at least a portion of incident photons having wavelengths within a first spectral range into photons having wavelengths in a second spectral range that has longer wavelengths than the first spectral range, and converting at least a portion of the photons having wavelengths in the second spectral range to electric power.

### BRIEF DESCRIPTION OF THE DRAWINGS

Additional features of this invention are provided in the following detailed description of various embodiments of the invention with reference to the drawings. Furthermore, the above-discussed and other attendant advantages of the present invention will become better understood by reference to the detailed description when taken in conjunction with the accompanying drawings, in which:

FIG. 1 is a schematic illustration of a photovoltaic device according to an embodiment of the current invention;

FIG. 2 is a schematic illustration of a photovoltaic device according to another embodiment of the current invention;

FIG. 3 is a schematic illustration of a photovoltaic device according to another embodiment of the current invention;

FIG. 4 shows measured external quantum efficiency versus wavelength for an example of a photovoltaic device constructed according to an embodiment of the current invention;

FIG. 5 shows measured current versus bias voltage to illustrate some concepts of the current invention in comparison to FIG. 6; and

FIG. 6 shows measured current versus bias voltage to illustrate some concepts of the current invention in comparison to FIG. 5.

### DETAILED DESCRIPTION

Great effort has been devoted to the development of organic light-emitting materials for information displays and solid-state lighting applications. Many of the organic materials employed in these devices exhibit excellent absorption in the UV, converting the incident UV radiation into visible light emission with very high photoluminescence efficiency. According to embodiments of the current invention, a “photon-conversion material” (PCM), a material that converts (harmful) short wavelength incident radiation into a longer and less harmful emission, is integrated into organic solar cells to utilize more fully the full solar spectrum. For example, the PCM can be materials that convert harmful UV into less harmful blue, green, red, or even infrared (IR) radiation. In addition, the PCM can also convert the photons from one portion of solar spectrum (not just the UV portion) into a different, usually longer wavelength portion of the electromagnetic spectrum. Therefore, one can convert the portion of solar energy that is less absorbed in the organic materials, for example, into the higher absorption wavelength region of organic or polymer materials. The conversion can be selective of a small portion of the solar spectrum, or it can be a continuous portion of the solar spectrum. In addition, if one just wants to protect the solar cells from damage, one can simply use an absorption material that has little re-emission to absorb a portion or a continuous part of the solar spectrum and not worry about re-emission of the longer wavelength photons. The PCMs can be organic, inorganic, and/or nano-particles, and it can be in the form of solid, gel, or liquid.

The use of photon conversion materials (PCM) can have other advantages other than efficiency of photon conversion. It is well-known that short wavelength photons, particular the UV, can be harmful for organic materials and can be the major source of degradation in organic solar cells. The photon conversion material can convert such harmful shorter wavelength photons into longer wavelength photons, both enhancing the solar energy conversion efficiency as well as diminishing the degradation of organic solar cells. The photon conversion material can be provided in, but are not limited to, the following formats: (a) An additional layer in front of the solar cell that can be a separate layer or a layer attached onto the reverse side of the solar cell substrate. (A protection layer can be placed in front of the PCM.) (b) PCM integrated into the transparent or semi-transparent substrates to provide protection to these materials as well as the solar cell itself. (c) An “envelop” into which the solar cell is inserted and also filled with PCM, in liquid, gel, sol-gel, nano-particle, or solid forms. By incorporating these materials into a solar cell by either the (a), (b), or (c) structures, device performance (efficiency, or lifetime, or both) may be enhanced by converting some unwanted short wavelength light into longer wavelength and less harmful photons.

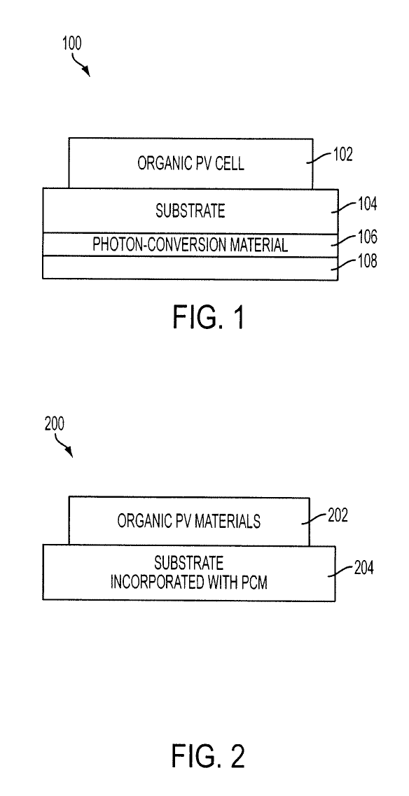

FIG. 1 is a schematic illustration of a photovoltaic device 100 according to an embodiment of the current invention. The photovoltaic device 100 has a photovoltaic cell 102 formed on or otherwise attached to a substrate 104. The substrate has a photon-conversion component 106 formed on or otherwise attached to a light-incident side of said substrate 104. The photovoltaic device 100 may optionally include a protective layer 108 on a light-incident side of the photon-conversion component 106. The photovoltaic cell 102 may be an organic or an inorganic photovoltaic cell. FIG. 1 illustrates an example in which photovoltaic cell 102 is an organic photovoltaic cell. It can be, for example, a small molecule organic photovoltaic cell and/or a polymer photovoltaic cell. The photovoltaic cell 102 may be constructed to have a transparent anode, a metal cathode and a layer of active material therebetween. The structure could also be more complex, for example, a layered structure that can provide higher photon conversion efficiency. The layer of active material may be an active organic material. In an embodiment, the layer of active material may be an organic triplet material. However, the general concepts of this invention are not limited to the particular structure and materials of the photovoltaic cell 102. The substrate 104 can be selected from conventional materials used to construct photovoltaic devices, for example materials that have sufficiently high transparency in the desired wavelength range of operation for the desired application.

The photon-conversion component 106 can be formed on or applied to the light-incident side of the substrate 104. Alternatively, the photon-conversion component 106 can also be formed on a separate film and attached in front of the light-incident side of the substrate 104. The photon-conversion component 106 may include organic, inorganic, phosphor, organic triplet, nanoparticles, and/or photonic bandgap materials in its composition. The protective layer 108, for embodiments in which it is included, may be placed in front of, or as a part of the photon-conversion component 106. For example, PCM may be incorporated into plastics or glass to provide a combined photon-conversion component and protection layer.

FIG. 2 is a schematic illustration of a photovoltaic device 200 according to an embodiment of the current invention. The photovoltaic device 200 has a photovoltaic cell 202 formed on or otherwise attached to a substrate 204. The photovoltaic cell 202 may be selected from photovoltaic cells similar to or substantially the same as photovoltaic cell 102 described above. The substrate 204 has PCM incorporated into it and is thus a photon-conversion component. The substrate 204 may include glass, a plastic and/or other materials. The lifetime of photon conversion materials can be extended by being incorporated into the substrate in some embodiments of this invention. One method to incorporate PCM into substrate 204 can be to prepare the substrate through a sol-gel process wherein the PCM materials are added during fabrication.

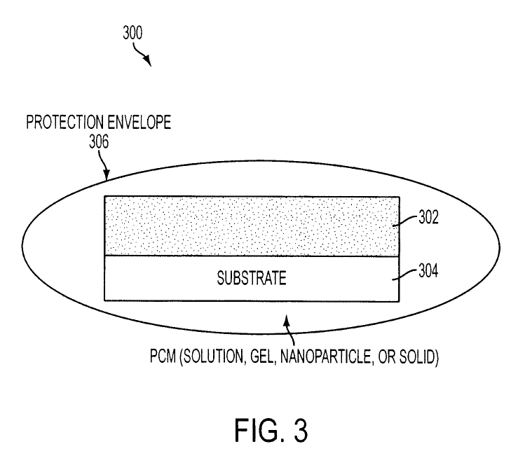

FIG. 3 is a schematic illustration of a photovoltaic device 300 according to an embodiment of the current invention. The photovoltaic device 300 has a photovoltaic cell 302 formed on or otherwise attached to a substrate 304. The photovoltaic cell 302 may be selected from photovoltaic cells similar to or substantially the same as photovoltaic cells 102 and 202 described above. The photovoltaic cell 302/substrate 304 structure is enclosed within a protective envelope 306. The protective envelope 306 also has PCM included within it to provide a photon-conversion layer. The PCM within the envelope 306 may be in the form of a liquid (e.g., solvent or oil based), a gel, nano-particles or a solid. The protective envelope 306 acts as a container to hold the photovoltaic cell 302/substrate 304 device as well as the photon-conversion materials. The outside of the protective envelope 306 can act as a first level of protection from the environment. Inert gas such as argon and/or nitrogen can be included inside the envelope such that it provides pressure to prevent oxygen and other harmful gas or moisture from penetrating into the envelope 306 to reach the photovoltaic cell 302.

### Example

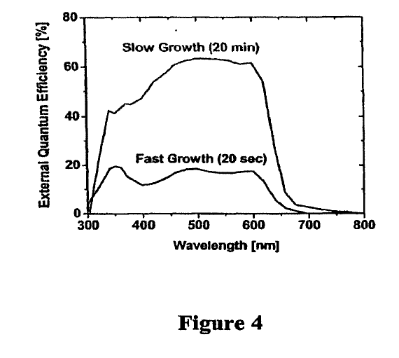

In a particular example, we use a P3HT:PCBM system with a slow growth method to demonstrate some concepts. The EQE spectrum vs. wavelength is shown in FIG. 4. At UV region (300-400 nm), the EQE is ˜40% while in visible region (450-600 nm), EQE is over 60%. By utilizing a blue light-emitting polymer, which emits blue light (peak at 450 nm), this system provides an example of some concepts of this invention.

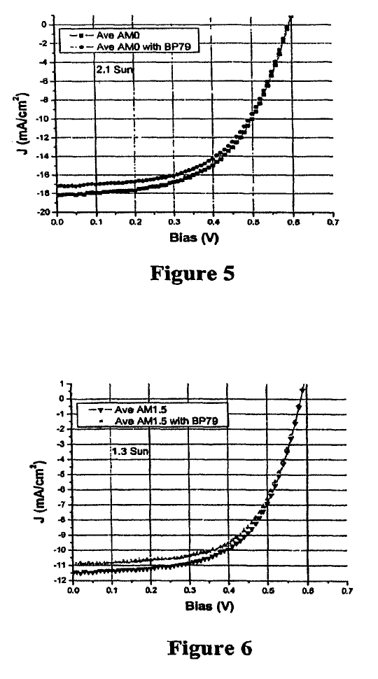

FIGS. 5 and 6 show the effect of adding blue polyfluorene on the reverse side of the solar cell glass substrates. Testing was under AM0 (2.1 Sun) and AM1.5 (1.3 Sun), respectively. After adding the blue polymer, a very minor efficiency drop of 5% was observed in both cases. Although the efficiency has a slight drop due to comparable quantum efficiency in UV and visible regions, and non perfect photoluminescence (PL) efficiency of the light, the lifetime of the cell increases due to reduced damage from UV light to polymer solar cells.

The invention has been described in detail with respect to various embodiments, and it will now be apparent from the foregoing to those skilled in the art that changes and modifications may be made without departing from the invention in its broader aspects, and the invention, therefore, as defined in the claims is intended to cover all such changes and modifications as fall within the true spirit of the invention.

We claim:

1. A photovoltaic device, comprising:
a photovoltaic cell; and
a photon-conversion component provided at least one of proximate to and integral with said photovoltaic cell, said photon-conversion component comprising a photon-conversion material,
wherein said photon-conversion material, while said photovoltaic device is in operation, converts photons in a spectral region comprising a first wavelength to photons in a spectral region comprising a second wavelength, said second wavelength being longer than said first wavelength, wherein photons having said second wavelength are at least one of less damaging to said photovoltaic cell than photons having said first wavelength or converted more efficiently to an electrical current than photons having said first wavelength.

2. A photovoltaic device according to claim 1, further comprising a substrate upon which said photovoltaic cell is formed,
wherein said photon-conversion component is formed on a light-incident side of said substrate.

3. A photovoltaic device according to claim 2, further comprising a protective layer formed on a light-incident side of said photon-conversion material, said protective layer being suitable to block at least a portion of incident photons at wavelengths that are harmful to at least one of said photovoltaic cell, said substrate and said photon-conversion component.

4. A photovoltaic device according to claim 3, wherein said protective layer is at least one of a light absorbing layer or a reflection coating layer that is constructed to reflect at least some harmful light back.

5. A photovoltaic device according to claim 3, wherein said protective layer is a reflection layer constructed to reflect at least a portion of photons in said first spectral range and serves as an anti-reflection layer for photons in said second spectral range.

6. A photovoltaic device according to claim 3, wherein said protective layer is a reflection layer constructed to reflect at least a portion of photons in said first spectral range and is constructed to provide multiple internal reflections for photons in said second spectral range within said photovoltaic cell to allow said photovoltaic cell to better absorb long wavelength photons via a multiple reflection process within the photovoltaic cell.

7. A photovoltaic device according to claim 1, further comprising a substrate upon which said photovoltaic cell is formed, said substrate comprising said photon-conversion material in its composition.

8. A photovoltaic device according to claim 7, wherein said substrate is provided on a light-incident side of said photovoltaic cell.

9. A photovoltaic device according to claim 1, further comprising a protective envelope in which said photovoltaic cell and said photon-conversion component are enclosed.

10. A photovoltaic device according to claim 9, wherein said envelope is a glass envelope comprising two glass plates in which said photovoltaic cell and said photon-conversion component are sandwiched between said two glass plates, and wherein said photovoltaic device is suitable to be mounted on a building as a window to generate electricity.

11. A photovoltaic device according to claim 10, wherein a vacuum is created between said two glass plates to further protect said photovoltaic cell.

12. A photovoltaic device according to claim 9, further comprising an inert gas enclosed in said protective envelope.

13. A photovoltaic device according to claim 1, wherein said photon-conversion material is selected from at least one of organic photon-conversion materials, inorganic photon-conversion materials, phosphors, organic triplet compounds, nano-particles and photonic bandgap materials.

14. A photovoltaic device according to claim 1, wherein said photon-conversion material has the form of at least one of a liquid, a gel, a sol-gel, nano-particles, or a solid.

15. A photovoltaic device according to claim 1, wherein said photovoltaic cell is an organic photovoltaic cell.

16. A photovoltaic device according to claim 15, wherein said organic photovoltaic cell is a small molecule organic photovoltaic cell.

17. A photovoltaic device according to claim 15, wherein said organic photovoltaic cell is a oligomer photovoltaic cell.

18. A photovoltaic device according to claim 15, wherein said organic photovoltaic cell is a polymer photovoltaic cell.

19. A photovoltaic device according to claim 1, wherein said photovoltaic cell is an inorganic photovoltaic cell.

20. A method of producing electricity, comprising:
converting at least a portion of incident photons having wavelengths within a first spectral range into photons in a second spectral range that has longer wavelengths than said first spectral range; and
converting at least some of said converted photons to electric power.
